(19) United States
(12) Patent Application Publication
(10) Pub. No.: US 2023/0197414 A1
(43) Pub. Date: Jun. 22, 2023

(54) SUBSTRATE TREATING APPARATUS AND METHOD THEREOF

(71) Applicant: SEMES CO., LTD., Chungcheongnam-do (KR)

(72) Inventors: Min Jung CHOI, Gyeonggi-do (KR); Ban Seok YOU, Seoul (KR); Woo Seok JANG, Gyeonggi-do (KR); Ki Duk TAK, Gyeonggi-do (KR)

(21) Appl. No.: 18/081,685

(22) Filed: Dec. 15, 2022

(30) Foreign Application Priority Data
Dec. 17, 2021 (KR) 10-2021-0182182

(51) Int. Cl. H01J 37/32

(52) U.S. Cl. CPC H01J 37/3244; H01J 37/32743; H01J 2237/334; H01J 37/32568; H01J 37/32082

(57) ABSTRACT

Provided are a substrate treating apparatus and a method thereof that can improve pattern roughness when an etching process is performed for a substrate. The substrate treating method comprises: inserting a substrate into a substrate treating apparatus; injecting a first process gas into the substrate treating apparatus and treating the substrate to a first plasma using the first process gas; and injecting a second process gas into the substrate treating apparatus and treating the substrate to a second plasma using the second process gas, wherein at least some components of the second process gas differ from those of the first process gas.

### CROSS-REFERENCE TO RELATED APPLICATION

This application claims priority from Korean Patent Application No. 10-2021-0182182 filed on Dec. 17, 2021 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a substrate treating apparatus and a method thereof. More particularly, the present disclosure relates to a substrate treating apparatus and a method thereof that can be applied to manufacture a semiconductor device.

### 2. Description of the Related Art

An image sensor is one of semiconductor devices that convert optical information into an electrical signal. The image sensor may include a charge coupled device (CCD) image sensor and a complementary metal oxide semiconductor (CMOS) image sensor. The CCD image sensor has the advantages of excellent image quality, excellent noise or afterimage processing effects, while the CMOS image sensor has the advantages of low power consumption and being relatively cheaper than the CCD image sensor.

### SUMMARY

When the CMOS image sensor is manufactured, an etch back process (or a blank etch process) may be performed for a lens applied to an image sensor.

However, since pattern roughness affects pixel light interference reduction and image sensor refinement in the etch back process, improvement of pattern roughness is an essential factor in the process of manufacturing the CMOS image sensor.

Technical aspects to be achieved through one embodiment by the present disclosure provide a substrate treating apparatus and a method thereof that can improve pattern roughness when an etching process is performed for a substrate.

The technical aspects of the present disclosure are not restricted to those set forth herein, and other unmentioned technical aspects will be clearly understood by one of ordinary skill in the art to which the present disclosure pertains by referencing the detailed description of the present disclosure given below.

In order to achieve the technical aspects, one aspect of a substrate treating method of the present disclosure may include: inserting a substrate into a substrate treating apparatus; injecting a first process gas into the substrate treating apparatus and treating the substrate to a first plasma using the first process gas; and injecting a second process gas into the substrate treating apparatus and treating the substrate to a second plasma using the second process gas, and at least some components of the second process gas differ from those of the first process gas.

In the treatment of the substrate to a second plasma, the first process gas may be used together.

The second process gas may include a first component commonly included in the first process gas and a second component not included in the first process gas.

The first component may be a fluorine component, and the second component may be a hydrogen component.

The second process gas may be injected in a larger amount than the first process gas.

The injection amount of the second process gas may be 1.5 to 2 times greater than the injection amount of the first process gas.

The first process gas may be an etching gas and the second process gas may be a deposition gas, or the first process gas and the second process gas may be etching gases.

The first process gas may be CF4 gas, and the second process gas may be CHF3 gas.

The second process gas may be mixed with the first process gas and then injected into the substrate treating apparatus.

The second process gas may be injected into the substrate treating apparatus separately from the first process gas.

The substrate treating apparatus may include: a process gas supply source configured to supply the first process gas and the second process gas; and a process gas supplying line configured to connect the process gas supply source and the substrate treating apparatus, and the second process gas may be mixed with the first process gas in the process gas supply source.

The substrate treating apparatus may include: a first process gas supply source configured to supply the first process gas; a second process gas supply source configured to supply the second process gas; and a process gas supplying line having one end connected to the substrate treating apparatus and the other end branched and connected to the first process gas supply source and the second process gas supply source, respectively, and the second process gas may be mixed with the first process gas when moving via the process gas supplying line.

One of the first process gas and the second process gas may be supplied via a first hole formed to penetrate an upper cover of the substrate treating apparatus, and the other gas may be supplied via a second hole formed to penetrate a sidewall of the substrate treating apparatus, or the first process gas and the second process gas may be supplied via one of the first hole and the second hole.

The substrate treating method may include an etch back process.

The substrate treating method may be applied when manufacturing a lens module of a CMOS image sensor.

In order to achieve the technical aspects, the other aspect of the substrate treating method of the present disclosure may include: inserting a substrate into a substrate treating apparatus; injecting a first process gas into the substrate treating apparatus and treating the substrate to a first plasma using the first process gas; and continuously injecting the first process gas into the substrate treating apparatus, additionally injecting a second process gas into the substrate treating apparatus, and treating the substrate to a second plasma using the first process gas and the second process gas, and the second process gas may include a first component commonly included in the first process gas and a second component not included in the first process gas, the first component may be a fluorine component and the second component may be a hydrogen component, and the second process gas may be injected in a larger amount than the first process gas.

In order to achieve the technical aspects, one aspect of a substrate treating apparatus of the present disclosure may include: a housing; a substrate support unit installed in the housing and configured to support the substrate; a plasma generation unit including a first electrode disposed in an upper part of the housing, a second electrode disposed to face the first electrode and included in the substrate support unit, a first high frequency power supply configured to supply RF power to the first electrode, and a second high frequency power supply configured to supply the RF power to the second electrode; and a process gas supplying unit connected to the housing via a hole formed to penetrate an upper cover or a sidewall of the housing and configured to supply a process gas for treating the substrate into the housing, and the process gas includes a first process gas and a second process gas in which at least some components are different from those of the first process gas.

The process gas supplying unit may first supply the first process gas and then supply the first process gas and the second process gas together.

The process gas supplying unit may supply a larger amount of the second process gas than the first process gas.

The process gas supplying unit may supply CF4 gas as the first process gas and CHF3 gas as the second process gas.

Details of other embodiments are included in the detailed description and drawings.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a cross-sectional view illustrating an internal structure of a substrate treating apparatus according to one embodiment of the present disclosure;

FIG. 2 is a cross-sectional view illustrating the internal structure of the substrate treating apparatus according to another embodiment of the present disclosure;

FIG. 3 is a first exemplary diagram describing a variety of embodiments of a process gas supplying unit constituting the substrate treating apparatus according to one embodiment of the present disclosure;

FIG. 4 is a second exemplary diagram describing a variety of embodiments of the process gas supplying unit constituting the substrate treating apparatus according to one embodiment of the present disclosure;

FIG. 5 is a third exemplary diagram describing a variety of embodiments of the process gas supplying unit constituting the substrate treating apparatus according to one embodiment of the present disclosure;

FIG. 6 is a flowchart describing a substrate treating process of the substrate treating apparatus according to one embodiment of the present disclosure;

FIG. 7 is an enlarged view of a surface of a substrate treated according to a conventional substrate treating process;

FIG. 8 is an enlarged view of a surface of a substrate treated according to the substrate treating process of the present disclosure; and

FIG. 9 is a flowchart illustrating a substrate treating process of the substrate treating apparatus according to another embodiment of the present disclosure.

### DETAILED DESCRIPTION OF THE EMBODIMENTS

Hereinafter, embodiments of the present disclosure will be described with reference to the attached drawings. The same reference numerals indicate the same elements throughout the specification, and redundant descriptions thereof will be omitted.

The present disclosure relates to a substrate treating apparatus and a method thereof that can improve pattern roughness when a substrate is treated via an etching process. Specifically, the present disclosure relates to a substrate treating apparatus and a method thereof that can improve pattern roughness when treating a substrate used to manufacture a comprehensive metal oxide semiconductor (CMOS) image sensor. Hereinafter, the present disclosure will be described in detail with reference to the drawings.

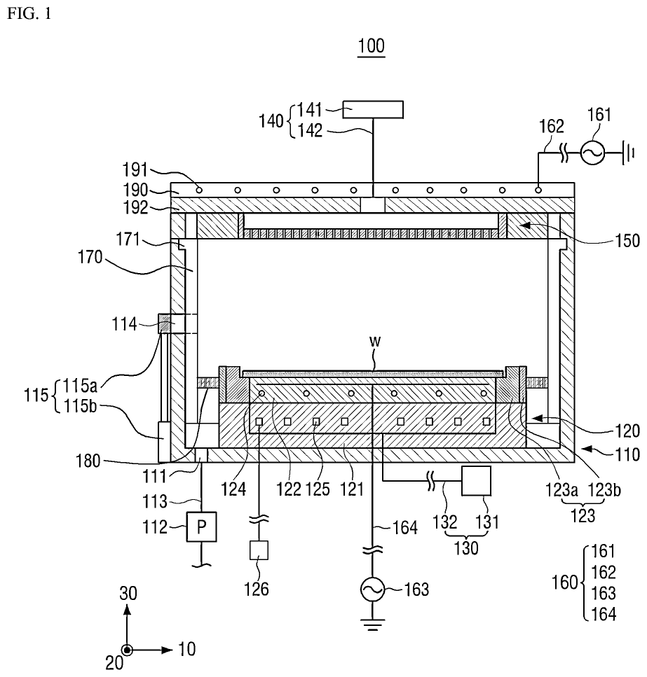

FIG. 1 is a cross-sectional view illustrating an internal structure of a substrate treating apparatus according to one embodiment of the present disclosure.

Referring to FIG. 1, a substrate treating apparatus 100 may include a housing 110, a substrate support unit 120, a cleaning gas supplying unit 130, a process gas supplying unit 140, a shower head unit 150, a plasma generation unit 160, a liner unit 170, a baffle unit 180 and an antenna unit 190.

The substrate treating apparatus 100 is an apparatus for treating a substrate W (e.g., a wafer) using plasma. The substrate treatment apparatus 100 may be implemented with a deposition process chamber or an etching process chamber, thereby enabling the substrate W to be deposited or etched in a vacuum environment. However, the present embodiment is not limited thereto. The substrate treating apparatus 100 may be implemented with a cleaning process chamber, thereby enabling the substrate W to be dry-cleaned.

The housing 110 is meant to provide a process of treating the substrate W using plasma, i.e., a space where a plasma process is executed. The housing 110 may include an exhaust hole 111 formed at a lower part thereof.

The exhaust hole 111 may be connected to an exhaust line 113 in which a pump 112 is mounted. The exhaust hole 111 may discharge by-products generated during the plasma process and gas remaining in the housing 110 to the outside of the housing 110 via the exhaust line 113. In that case, an inner space of the housing 110 may be decompressed to a predetermined pressure.

The housing 110 may have an opening 114 formed on a sidewall thereof. The opening 114 may function as a passage through which the substrate W enters and exits the housing 110. The opening 114 may be automatically opened and closed by, for example, a door assembly 115.

The door assembly 115 may include an outer door 115a and a door driver 115b. The outer door 115a is provided on the outer wall of the housing 110. The outer door 115a may be moved in the height direction of the substrate treating apparatus 100, i.e., a third direction 30, via the door driver 115b. The door driver 115b may operate using one selected from a motor, a hydraulic cylinder, and a pneumatic cylinder.

The substrate support unit 120 is installed in an inner lower region of the housing 110. The substrate support unit 120 may support the substrate W using an electrostatic force. However, the present embodiment is not limited thereto. The substrate support unit 120 can support the substrate W in a variety of ways such as mechanical clamping and vacuum.

When the substrate support unit 120 supports the substrate W using the electrostatic force, the substrate support unit 120 may include a base 121 and an electrostatic chuck (ESC) 122.

The electrostatic chuck 122 is a substrate support member that supports the substrate W mounted on an upper part thereof using the electrostatic force. The electrostatic chuck 122 may be disposed on the base 121 and may be formed of a ceramic material.

The ring assembly 123 is provided to surround an outer edge region of the electrostatic chuck 122. The ring assembly 123 may include a focus ring 123a and an edge ring 123b.

The focus ring 123a may be formed inside the edge ring 123b and provided to surround the outer edge region of the electrostatic chuck 122. The focus ring 123a may serve to concentrate ions on the substrate W when a plasma process is advanced inside the housing 110, and may be formed of a silicon material.

The edge ring 123b may be formed outside the focus ring 123a and provided to surround an outer region of the focus ring 123a. The edge ring 123b may serve to prevent a side surface of the electrostatic chuck 122 from being damaged by plasma, and may be formed of an insulator material, for example, a quartz material.

A heating member 124 and a cooling member 125 are provided to maintain the substrate W at a process temperature when a substrate treating process is executed inside the housing 110. The heating member 124 may be provided as a hot wire to increase the temperature of the substrate W, and may be installed, for example, in the electrostatic chuck 122. The cooling member 125 may be provided as a cooling line through which a refrigerant flows to decrease the temperature of the substrate W and may be installed, for example, in the base 121.

Meanwhile, the cooling member 125 may receive the refrigerant using a cooling device 126. The cooling device 126 may be separately installed outside the housing 110.

The cleaning gas supplying unit 130 supplies a cleaning gas to remove foreign substances remaining in the electrostatic chuck 122 or the ring assembly 123. The cleaning gas supplying unit 130 may supply, for example, a nitrogen gas (N2 Gas) as a cleaning gas, and may include a cleaning gas supply source 131 and a cleaning gas supplying line 132.

The cleaning gas supplying line 132 transfers the cleaning gas supplied by the cleaning gas supply source 131. The cleaning gas supplying line 132 may be connected to a space between the electrostatic chuck 122 and the focus ring 123a, and the cleaning gas may move through the space to remove the foreign substances remaining on an edge of the electrostatic chuck 122 or an upper part of the ring assembly 123.

The process gas supplying unit 140 supplies a process gas to the inner space of the housing 110. The process gas supplying unit 140 may supply the process gas via a hole formed to penetrate an upper cover of the housing 110 or supply the process gas via a hole formed to penetrate a sidewall of the housing 110. The process gas supplying unit 140 may include a process gas supply source 141 and a process gas supplying line 142.

The process gas supply source 141 may supply gas used to treat the substrate W as the process gas, and the number of process gas supply sources 141 may be at least one in the substrate treating apparatus 100. When a plurality of process gas supply sources 141 are provided in the substrate treating apparatus 100, the plurality of process gas supply sources 141 may supply the same kind of process gas, which makes it possible to provide a large amount of gas within a short period of time and supply different kinds of process gases.

The process gas supplying line 142 transfers the process gas supplied by the process gas supply source 141 to the shower head unit 150. To this end, the process gas supplying line 142 may be provided to connect the process gas supply source 141 to the shower head unit 150.

Meanwhile, although not illustrated in FIG. 1, when the shower head unit 150 is divided into a plurality of modules, the process gas supplying unit 140 may further include a process gas distributor and a process gas distribution line for distributing the process gas to the respective modules of the shower head unit 150. The process gas distributor may be installed on the process gas supplying line 142 and may distribute the process gas supplied from the process gas supply source 141 to the respective modules of the shower head unit 150. The process gas distribution line may connect the process gas distributor to the respective modules of the shower head unit 150 and may transfer the process gas distributed by the process gas distributor to the respective modules of the shower head unit 150.

The shower head unit 150 may be disposed in the inner space of the housing 110 and may include a plurality of gas injection holes. Herein, the plurality of gas injection holes may be formed to penetrate the surface of a body of the shower head unit 150 at regular intervals on the body. The shower head unit 150 may uniformly inject the process gas supplied via the process gas supplying unit 140 onto the substrate W in the housing 110.

The shower head unit 150 may be installed in the housing 110 to face the electrostatic chuck 122 in a vertical direction (i.e., the third direction 30). In that case, the shower head unit 150 may be provided to have a larger diameter than the electrostatic chuck 122 and may be provided to have the same diameter as the electrostatic chuck 122. The shower head unit 150 may be form of a silicon material or a metal material.

Although not illustrated in FIG. 1, the shower head unit 150 may be divided into a plurality of modules. For example, the shower head unit 150 may be divided into three modules such as a first module, a second module and a third module. The first module may be disposed at a position corresponding to a center zone of the substrate W. The second module may be disposed to surround an outer side of the first module and may be disposed at a position corresponding to a middle zone of the substrate W. The third module may be disposed to surround an outer side of the second module and may be disposed at a position corresponding to an edge zone of the substrate W.

The plasma generation unit 160 generates plasma from gas remaining in a discharge space. Herein, the discharge space refers to a space disposed above the substrate W in the inner space of the housing 110.

The plasma generation unit 160 may generate plasma in the discharge space inside the housing 110 using an inductively coupled plasma (ICP) source. For example, the plasma generation unit 160 may generate plasma in the discharge space inside the housing 110 by using the antenna unit 190 as a first electrode and the electrostatic chuck 122 as a second electrode.

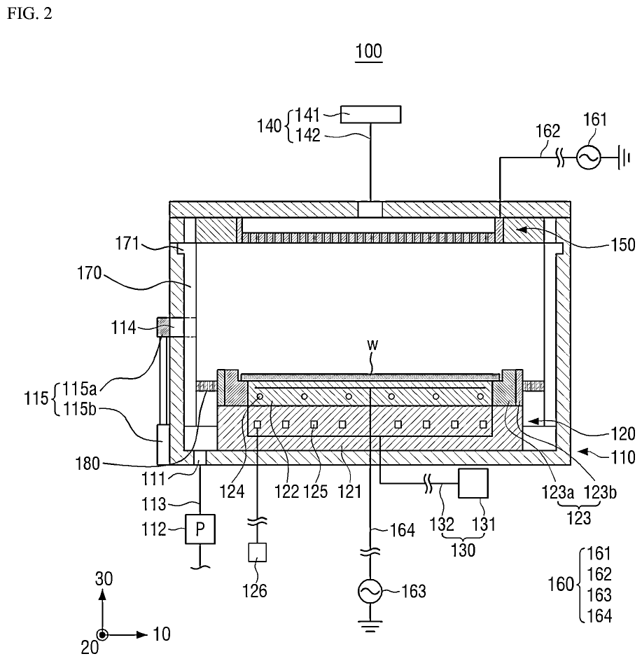

However, the present embodiment is not limited thereto. The plasma generation unit 160 can generate plasma in the discharge space inside the housing 110 by using a capacitively coupled plasma (CCP) source. For example, the plasma generation unit 160 may generate plasma in the discharge space inside the housing 110 by using the shower head unit 150 as the first electrode and the electrostatic chuck 122 as the second electrode. FIG. 2 is a cross-sectional view illustrating the internal structure of the substrate treating apparatus according to another embodiment of the present disclosure.

It will be described again with reference to FIG. 1.

The plasma generation unit 160 may include a first high frequency power source 161, a first transmission line 162, a second high frequency power source 163 and a second transmission line 164.

The first high frequency power source 161 applies RF power to the first electrode. The first high frequency power source 161 may serve to control characteristics of plasma in the substrate treating apparatus 100. For example, the first high frequency power source 161 may serve to control ion bombardment energy in the substrate treating apparatus 100.

The first high frequency power source 161 may be provided in the substrate treating apparatus 100 to be in a singular form, but a plurality of first high frequency power sources may be provided. When the plurality of first high frequency power sources 161 are provided in the substrate treating apparatus 100, they may be disposed in parallel on the first transmission line 162.

When the plurality of first high frequency power sources 161 are provided in the substrate treating apparatus 100, although not illustrated in FIG. 1, the plasma generation unit 160 may further include a first matching network electrically connected to the plurality of first high frequency power sources. Herein, when frequency power of different sizes is input from each of the first high frequency power sources, the first matching network may serve to match and apply the frequency power to the first electrode.

The first transmission line 162 connects the first electrode and the GND. The first high frequency power source 161 may be installed on the first transmission line 162.

Meanwhile, although not illustrated in FIG. 1, a first impedance matching circuit may be provided on the first transmission line 162 configured to connect the first high frequency power source 161 and the first electrode for the purpose of impedance matching. The first impedance matching circuit may serve as a lossless manual circuit, thus allowing maximum electrical energy to be transmitted from the first high frequency power source 161 to the first electrode.

The second high frequency power source 163 applies the RF power to the second electrode. The second high frequency power source 163 may serve as a plasma source that generates plasma in the substrate treating apparatus 100 or serve to control characteristics of the plasma together with the first high frequency power source 161.

The second high frequency power source 163 may be provided in the substrate treating apparatus 100 to be in a singular form, but a plurality of second high frequency power sources may be provided. When the plurality of second high frequency power sources 163 are provided in the substrate treating apparatus 100, they may be disposed in parallel on the second transmission line 164.

When the plurality of second high frequency power sources 163 are provided in the substrate treating apparatus 100, although not illustrated in FIG. 1, the plasma generation unit 160 may further include a second matching network electrically connected to the plurality of second high frequency power sources. Herein, when frequency power of different sizes is input from each of the second high frequency power sources, the second matching network may serve to match and apply the frequency power to the second electrode.

The second transmission line 164 connects the second electrode and the GND. The second high frequency power source 163 may be installed on the second transmission line 164.

Meanwhile, although not illustrated in FIG. 1, a second impedance matching circuit may be provided on the second transmission line 164 configured to connect the second high frequency power source 163 and the second electrode for the purpose of impedance matching.

The second impedance matching circuit may serve as a lossless manual circuit, thus allowing maximum electrical energy to be transmitted from the second high frequency power source 163 to the second electrode.

When the second high frequency power source 163 is installed on the second transmission line 164, the plasma generation unit 160 may apply multi frequencies to the substrate treating apparatus 100, thereby improving substrate treating efficiency of the substrate treating apparatus 100. However, the present embodiment is not limited thereto. The plasma generation unit 160 may be configured without including the second high frequency power source 163. In other words, the second high frequency power source 163 may not be installed on the second transmission line 164.

The liner unit or wall liner 170 is meant to protect the inside of the housing 110 from arc discharge generated during the process of exciting the process gas or impurities generated during the substrate treatment process. To this end, the liner unit 170 may be formed to cover an inner sidewall of the housing 110.

The liner unit 170 may include a support ring 171 formed on an upper portion thereof. The support ring 171 may protrude from the top of the liner unit 170 in an outward direction (i.e., a first direction 10), and may serve to fix the liner unit 170 to the housing 110.

The baffle unit 180 serves to exhaust by-products of a plasma process and unreacted gas. The baffle unit 180 may be installed in a space between the inner sidewall of the housing 110 and the substrate support unit 120 and provided in an annular ring shape. The baffle unit 180 may include a plurality of through holes that penetrates in the vertical direction (i.e., the third direction 30) to control the flow of the process gas.

The antenna unit 190 serves to generate a magnetic field and an electric field in the housing 110 to excite the process gas into plasma. To this end, the antenna unit 190 may include an antenna 191 provided to form a closed loop using a coil and may use the RF power supplied from the first high frequency power source 161.

The antenna unit 190 may be installed on an upper surface of the housing 110. In that case, the antenna 191 may be installed by using the width direction of the housing 110 (i.e., the first direction 10) as the longitudinal direction and may be provided to have a size corresponding to the diameter of the housing 110.

The antenna unit 190 may be formed to have a planar type. However, the present embodiment is not limited thereto. The antenna unit 190 can be formed to have a cylindrical structure. In that case, the antenna unit 190 may be installed to surround an outer sidewall of the housing 110.

Meanwhile, the antenna unit 190 may include a window module 192. The window module 192 may serve as an upper cover of the housing that, when opening an upper part of the housing 110, covers the upper part to seal the inner space of the housing 110.

The window module 192 may be formed of an insulating material (e.g., alumina (Al₂O₃)) as a dielectric window. The window module 192 may include a coating film formed on a surface thereof to suppress occurrence of particles when advancing the plasma inside the housing 110.

An etch back process may be applied when treating the substrate W to manufacture the CMOS image sensor. The etch back process may be applied, for example, when manufacturing a CMOS image sensor (CIS) lens module.

However, in the case of the CIS lens module, pattern roughness generated during the treatment of the substrate may affect light interference and refinement of image sensors. Therefore, the substrate treating process capable of improving the pattern roughness may be a decisive factor in manufacturing the CMOS image sensor.

In the present embodiment, when the substrate treating apparatus 100 treats the substrate W using the etch back process, the process gas supplying unit 140 may introduce a plurality of different kinds of process gases into the housing 110 to improve the pattern roughness. For example, the process gas supplying unit 140 may introduce the first process gas and the second process gas into the housing 110.

The process gas supplying unit 140 may include two process gas supply sources and two process gas supplying lines to introduce the first process gas and the second process gas into the housing 110. However, the present embodiment is not limited thereto. The process gas supplying unit 140 can include two process gas supply sources and one process gas supplying line. Meanwhile, the process gas supplying unit 140 can include one process gas supply source and one process gas supplying line.

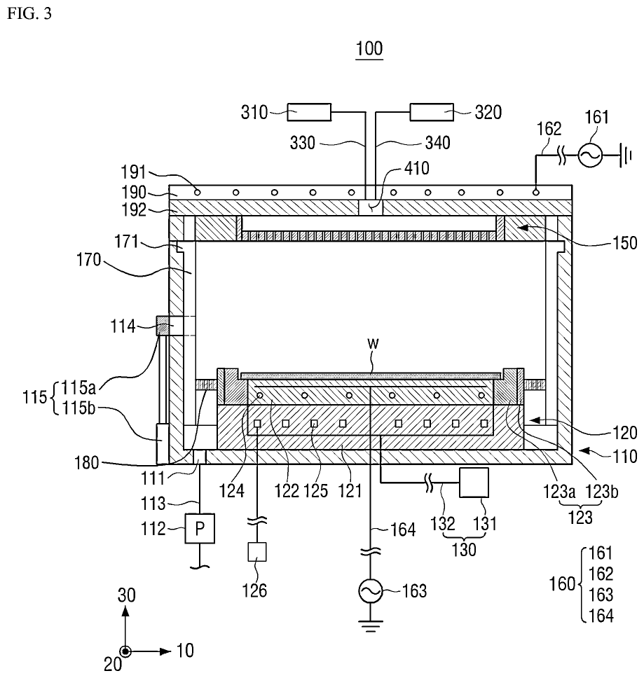

When the process gas supplying unit 140 includes two process gas supply sources and two process gas supplying lines, as illustrated in FIG. 3, it may include, for example, a first process gas supply source 310, a second process gas supply source 320, a first process gas supplying line 330 and a second process gas supplying line 340. FIG. 3 is a first exemplary diagram describing a variety of embodiments of the process gas supplying unit constituting the substrate treating apparatus according to one embodiment of the present disclosure.

The first process gas supplying line 330 may connect the first process gas supply source 310 configured to supply the first process gas and a first hole 410 formed to penetrate the upper cover of the housing 110. In that case, the first process gas may be introduced into the housing 110 and then moved downwards in the vertical direction and be supplied onto the substrate W.

However, the present embodiment is not limited thereto. The first process gas supplying line 330 can connect the first process gas supply source 310 and a hole formed to penetrate the sidewall of the housing 110. In that case, the first process gas may be introduced into the housing 110 and then moved in a downward inclined direction and be supplied onto the substrate W.

The second process gas supplying line 340 may connect the second process gas supply source 320 configured to supply the second process gas and the first hole 410. In that case, the second process gas may be introduced into the housing 110 and then moved downwards in the vertical direction and be supplied onto the substrate W.

However, the present embodiment is not limited thereto. The second process gas supplying line 340 can connect the second process gas supply source 320 and the hole formed to penetrate the sidewall of the housing 110. In that case, the second process gas may be introduced into the housing 110 and then moved in the downward inclined direction and be supplied onto the substrate W.

The former case illustrates that the first process gas and the second process gas move in the same direction and are supplied onto the substrate W. However, the present embodiment is not limited thereto. The first process gas and the second process gas can move in different directions and be supplied on the substrate W as in the latter case.

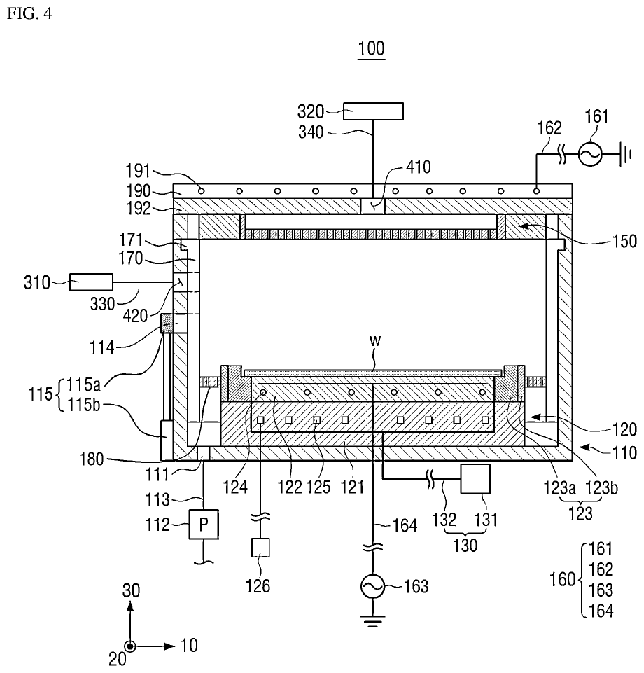

For example, when the process gas supplying unit 140 includes the first process gas supply source 310, the second process gas supply source 320, the first process gas supplying line 330 and the second process gas supplying line 340, as illustrated in FIG. 4, the first process gas supplying line 330 may connect the first process gas supply source 310 and the second hole 420 formed to penetrate the sidewall of the housing 110, and in that case, the first process gas may be introduced into the housing 110 and then moved in the downward inclined direction and be supplied onto the substrate W.

On the other hand, the second process gas supplying line 340 connects the second process gas supply source 320 and the first hole 410 identically to the case illustrated in FIG. 3, and in that case, the second process gas may be introduced into the housing 110 and then moved downwards in the vertical direction and be supplied onto the substrate W. FIG. 4 is a second exemplary diagram describing a variety of embodiments of the process gas supplying unit constituting the substrate treating apparatus according to one embodiment of the present disclosure.

Alternatively, the first process gas supplying line 330 can connect the first process gas supply source 310 and the first hole 410, and the second process gas supplying line 340 can connect the second process gas supply source 320 and the second hole 420.

The process gas supplying unit 140 described with reference to FIGS. 3 and 4 illustrates a case in which it includes two process gas supply sources and two process gas supplying lines. As described above, the process gas supplying unit 140 may include two process gas supply sources and one process gas supplying line. This will be described below.

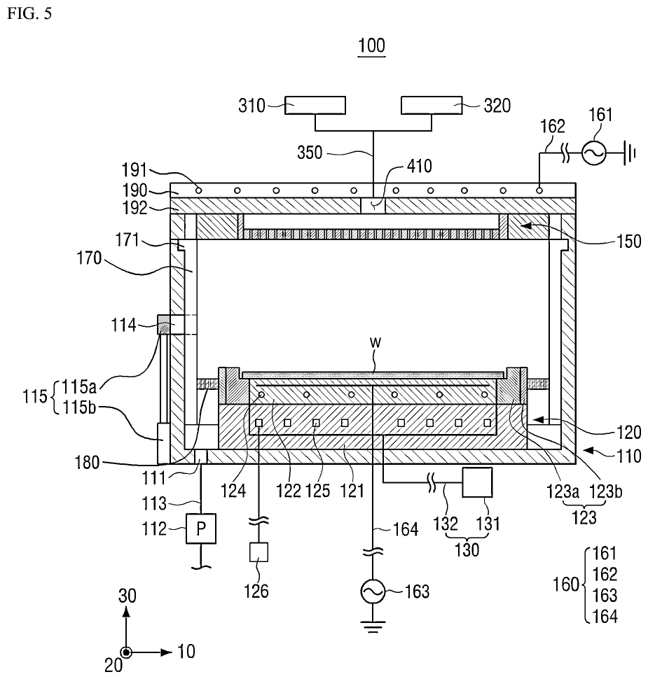

When the process gas supplying unit 140 includes two process gas supply sources and one process gas supplying line, as illustrated in FIG. 5, it may include, for example, the first process gas supply source 310, the second process gas supply source 320 and a third process gas supplying line 350. FIG. 5 is a third exemplary diagram describing a variety of embodiments of the process gas supplying unit constituting the substrate treating apparatus according to one embodiment of the present disclosure.

The third process gas supplying line 350 may connect the first process gas supply source 310 and the first hole 410 formed to penetrate the upper cover of the housing 110. Furthermore, the third process gas supplying line 350 may connect the second process gas supply source 320 and the first hole 410. In that case, the first process gas and the second process gas may be introduced into the housing 110 and then moved downwards in the vertical direction and may be supplied onto the substrate W.

However, the present embodiment is not limited thereto. The third process gas supplying line 350 may connect the first process gas supply source 310 and the second hole 420 formed to penetrate the sidewall of the housing 110, as well as connect the second process gas supply source 320 and the second hole 420. In that case, the first process gas and the second process gas may be introduced into the housing 110 and then moved in the downward inclined direction and may be supplied onto on the substrate W.

Meanwhile, when the process gas supplying unit 140 includes one process gas supply source and one process gas supplying line, as illustrated in FIG. 1, it may include, for example, a process gas supply source 141 and a process gas supplying line 142.

As described above, the process gas supplying line 142 may supply different types of first and second process gases onto the substrate W in the housing 110. Herein, one of the first process gas and the second process gas may be gas for etching the substrate, while the other gas may be gas for depositing the substrate. Alternatively, both the first process gas and the second process gas may be gas for etching the substrate.

The first process gas and the second process gas may include at least one component in common. For example, both the first process gas and the second process gas may include a fluorine component. Furthermore, one of the first process gas and the second process gas may include at least one certain component, and the other gas may not include the certain component. For example, one of the first process gas and the second process gas may include a hydrogen component, and the other gas may not include the hydrogen component.

Meanwhile, the first process gas and the second process gas may differentially include at least one component. For example, the first process gas may include a component (e.g., a hydrogen component) that is not included in the second process gas, while the second process gas may include a component that is not included in the first process gas.

When the process gas supplying unit 140 supplies the first process gas and the second process gas, one of the first process gas and the second process gas may be first supplied, and after a predetermined time elapses, the other gas may be supplied together with one gas. That is, one of the first process gas and the second process gas may be first supplied and continuously supplied, while the other gas may be supplied only after a predetermined time elapses from the time when one gas is supplied. For example, when the process gas supplying unit 140 includes two process gas supply sources and two process gas supplying lines, one of the first process gas and the second process gas may be first supplied, and then the other gas may be supplied together with one gas. Alternatively, when the process gas supplying unit 140 includes two process gas supply sources and one process gas supplying line, one of the first process gas and the second process gas may be first supplied, and then the other gas may be supplied together with one gas.

However, the present embodiment is not limited thereto. The first process gas and the second process gas can be simultaneously supplied. For example, when the process gas supplying unit 140 includes two process gas supply sources and two process gas supplying lines, the first process gas and the second process gas may be simultaneously supplied. Alternatively, when the process gas supplying unit 140 includes two process gas supply sources and one process gas supplying line, the first process gas and the second process gas may be simultaneously supplied. Alternatively, when the process gas supplying unit 140 includes one process gas supply source and one process gas supplying line, the first process gas and the second process gas may be simultaneously supplied.

Meanwhile, in the present embodiment, one of the first process gas and the second process gas may be supplied, and after a predetermined time elapses, one gas may be stopped, while the other gas may be supplied. For example, when the process gas supplying unit 140 includes two process gas supply sources and two process gas supplying lines, or when the process gas supplying unit 140 includes two process gas supply sources and one process gas supplying line, the first process gas and the second process gas may be supplied as described above.

When the process gas supplying unit 140 supplies the first process gas and the second process gas, the first process gas and the second process gas may be supplied into the housing 110 in a state where the first and second gases are not mixed, or may be supplied into the housing 110 after mixing the first and second gases.

In the former case, for example, when the process gas supplying unit 140 includes two process gas supply sources and two process gas supplying lines, the first process gas and the second process gas may be supplied into the housing 110 in the state where the first and second gases are not mixed. When the first process gas and the second process gas are supplied into the housing 110 in the state where the first and second gases are not mixed, the first process gas and the second process gas may be mixed only after they are introduced into the housing 110. Alternatively, the first process gas and the second process gas may not be mixed until plasma is generated by the plasma generation unit 160, the first electrode and the second electrode.

In the latter case, the first process gas and the second process gas may be supplied into the housing 110 after they are mixed in the process gas supply source, or may be supplied into the housing 110 after they are mixed in the process gas supplying line.

For example, when the process gas supplying unit 140 includes two process gas supply sources and one process gas supplying line, the first process gas and the second process gas may be mixed while they move into the housing 110 along the process gas supplying line. In other words, the first process gas and the second process gas may be supplied into the housing 110 after they are mixed in the process gas supplying line.

Meanwhile, when the process gas supplying unit 140 includes one process gas supply source and one process gas supplying line, the first process gas and the second process gas may be mixed in the process gas supply source. In that case, the first process gas and the second process gas may be supplied into the housing 110 after they are mixed in the process gas supply source.

The operation of the process gas supplying unit 140 constituting the substrate treating apparatus 100 has been described with reference to FIGS. 3 to 5. Hereinafter, a substrate treating method of the substrate treating apparatus 100 will be described.

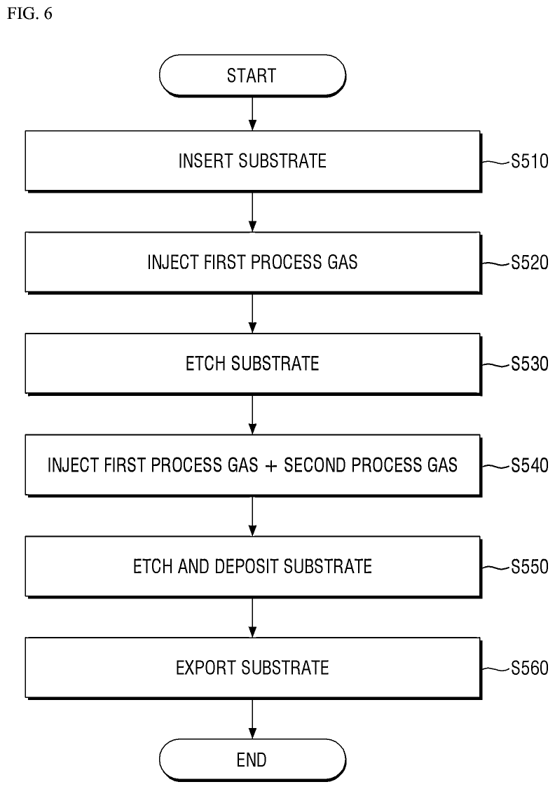

FIG. 6 is a flowchart describing a substrate treating process of the substrate treating apparatus according to one embodiment of the present disclosure. The following description will be referenced to FIG. 6.

First, the opening 114 is opened, and the substrate W is inserted into the housing 110 (S510).

Then, the first process gas is introduced into the housing 110 using the process gas supplying unit 140 (S520). Herein, the first process gas may include the fluorine component commonly included in the second process gas. The first process gas may be, for example, CF4 gas.

Then, plasma for treating the substrate W is generated by using the plasma generation unit 160, the first electrode and the second electrode (S530). The plasma may etch the substrate W (Etch).

Then, the second process gas following the first process gas is introduced into the housing 110 using the process gas supplying unit 140 (S540). In that case, the second process gas may be introduced into the housing 110 in a state where it is mixed with the first process gas, or may be introduced into the housing 110 in a state where it is present separately from the first process gas, i.e., not mixed with the first process gas.

As described above, the second process gas may include the fluorine component commonly included in the first process gas. Furthermore, the second process gas may include a hydrogen component that is not included in the first process gas. The second process gas may be, for example, CHF3 gas.

The second process gas may be supplied into the housing 110 at a ratio greater than that of the first process gas. For example, the second process gas may be supplied into the housing 110 at a rate 1.5 to 2 times greater than that of the first process gas. As described above, when the first process gas is CF4 gas and the second process gas is CHF3 gas, the first process gas and the second process gas may be supplied into the housing 110 by applying a ratio of CF4 gas: CHF3 gas=100:180. However, the present embodiment is not limited thereto. The second process gas can be supplied into the housing 110 at the same ratio as the first process gas.

Then, the plasma for treating the substrate W is generated by using the plasma generation unit 160, the first electrode and the second electrode (S550). The plasma may deposit the substrate W (deposition). Upon completing the etching treatment and the deposition treatment by the plasma, the substrate W may be exported thereafter (S560).

Meanwhile, in the present embodiment, the second process gas may be additionally injected while continuously advancing the step S530, so that the etching and deposition treatments for the substrate W can occur simultaneously. Alternatively, the steps S520 and S530 can be simultaneously advanced, followed by the steps S540 and S550.

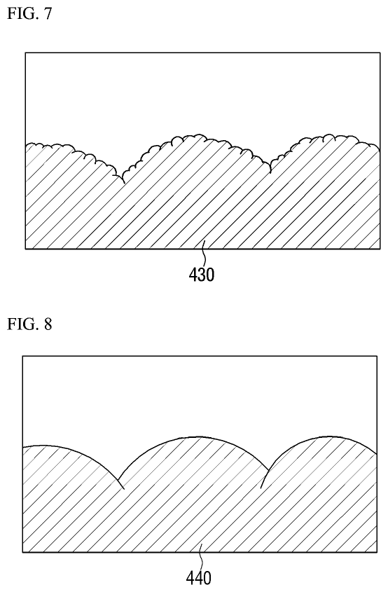

When treating the substrate W used to manufacture the CIS lens module using only the first process gas, the surface of the substrate has a very rough texture. FIG. 7 is an enlarged view of a surface of a substrate treated according to a conventional substrate treating process. When checking a short pattern image of the CIS lens module treated according to the conventional substrate treating process using a scanning electron microscope (SEM), as illustrated in FIG. 7, it can be seen that an upper surface of a pattern 430 is uneven and is formed very rough.

On the contrary, as described in FIG. 6, when treating the substrate W using not only the first process gas but also the second process gas, the surface of the substrate may have a very soft texture. FIG. 8 is an enlarged view of a surface of the substrate treated according to the substrate treating process of the present disclosure. When checking the short pattern image of the CIS lens module treated according to the substrate treating process of the present disclosure using the SEM identically to the case illustrated in FIG. 7, as illustrated in FIG. 8, the upper surface of the pattern 440 is smoothly formed, from which it can be seen that the pattern roughness is significantly improved as compared with the conventional art.

The substrate treating process described with reference to FIG. 6 is an example in which the first process gas is first supplied and, after a predetermined time elapses, the second process gas is supplied together with the first process gas. As described above, in the present embodiment, the first process gas is first supplied, and after a predetermined time elapses, the second process gas can be supplied instead of the first process gas. This will be described below.

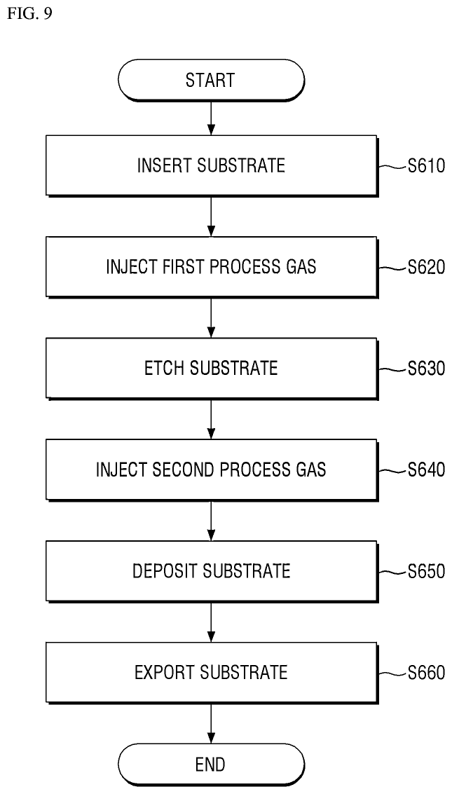

FIG. 9 is a flowchart illustrating a substrate treating process of the substrate treating apparatus according to another embodiment of the present disclosure. The following description refers to FIG. 9.

First, the opening 114 is opened, and the substrate W is inserted into the housing 110 (S610).

Then, the first process gas is introduced into the housing 110 using the process gas supplying unit 140 (S620). Herein, the first process gas may include the fluorine component commonly included in the second process gas. The first process gas may be, for example, CF4 gas.

Then, the plasma for treating the substrate W is generated by using the plasma generation unit 160, the first electrode and the second electrode (S630). The plasma may etch the substrate W (etch).

Then, the second process gas is introduced into the housing 110 using the process gas supplying unit 140 (S640). Herein, the second process gas may include the fluorine component commonly included in the first process gas and include a hydrogen component not included in the first process gas. The second process gas may be, for example, CHF3 gas.

Then, the plasma for treating the substrate W is generated by using the plasma generation unit 160, the first electrode and the second electrode (S650). The plasma may deposit the substrate W (deposition). Upon completing the etching treatment and the deposition treatment by the plasma, the substrate W may be exported thereafter (S660).

The present disclosure relates to the etch back process of manufacturing the CIS lens module, and more particularly, to the substrate treating method for improving pattern roughness. When a main etch step as a single step (1 step) is conducted using only CF4 gas, it is difficult to improve the pattern roughness.

In the present disclosure, the effect of improving the pattern roughness can be obtained by developing the condition (2 step recipe) where polymer deposition is treated in spite of having an etching facility, with two steps (2 step), i.e., with the main etch step+the treatment step, using CF4 gas and CHF3 gas. In the present disclosure, the CF4 gas and the CHF3 gas may be used as an etching gas and a deposition gas, respectively, and the surface roughness of the substrate may thus be improved by etching+deposition treatment after etching. Specifically, after etching the substrate with the CF4 gas, the substrate may be deposited with the CF4 gas and the CHF3 gas.

In the present disclosure, a deposition step may be added by adding the CHF3 gas. The present disclosure may proceed in two steps accordingly. During etching and deposition processes, a carbon-based polymer may be deposited on the pattern. According to the present disclosure, since the deposition may occur not only in the center region of the substrate W but also in the edge region thereof, a coating effect may be obtained throughout the entire surface of the substrate W, while the pattern roughness may be improved throughout the entire surface of the substrate W.

Although the embodiments of the present disclosure have been described above with reference to the accompanying drawings, the present disclosure is not limited to the disclosed embodiments, but may be implemented in various different ways, and the present disclosure may be embodied in many different forms without changing technical subject matters and essential features as will be understood by those skilled in the art. Therefore, embodiments set forth herein are exemplary only and not to be construed as a limitation.

What is claimed is:

1. A substrate treating method, comprising:
inserting a substrate into a substrate treating apparatus;
injecting a first process gas into the substrate treating apparatus and treating the substrate to a first plasma using the first process gas; and
injecting a second process gas into the substrate treating apparatus and treating the substrate to a second plasma using the second process gas,
wherein at least some components of the second process gas differ from those of the first process gas.

2. The substrate treating method of claim 1, wherein the treating of the substrate to a second plasma uses the first process gas together.

3. The substrate treating method of claim 1, wherein the second process gas includes a first component commonly included in the first process gas and a second component not included in the first process gas.

4. The substrate treating method of claim 3, wherein the first component is a fluorine component, and the second component is a hydrogen component.

5. The substrate treating method of claim 1, wherein the second process gas is injected in a larger amount than the first process gas.

6. The substrate treating method of claim 5, wherein the injection amount of the second process gas is 1.5 to 2 times greater than the injection amount of the first process gas.

7. The substrate treating method of claim 1, wherein the first process gas is an etching gas and the second process gas is a deposition gas, or the first process gas and the second process gas are etching gases.

8. The substrate treating method of claim 1, wherein the first process gas is CF4 gas, and the second process gas is CHF3 gas.

9. The substrate treating method of claim 2, wherein the second process gas is mixed with the first process gas and then injected into the substrate treating apparatus.

10. The substrate treating method of claim 2, wherein the second process gas is injected into the substrate treating apparatus separately from the first process gas.

11. The substrate treating method of claim 9, wherein the substrate treating apparatus comprises:
a process gas supply source configured to supply the first process gas and the second process gas; and
a process gas supplying line configured to connect the process gas supply source and the substrate treating apparatus,
wherein the second process gas is mixed with the first process gas in the process gas supply source.

12. The substrate treating method of claim 9, wherein the substrate treating apparatus comprises:
a first process gas supply source configured to supply the first process gas;
a second process gas supply source configured to supply the second process gas; and a process gas supplying line having one end connected to the substrate treating apparatus and the other end branched and connected to the first process gas supply source and the second process gas supply source, respectively,
wherein the second process gas is mixed with the first process gas when moving via the process gas supplying line.

13. The substrate treating method of claim 1, wherein one of the first process gas and the second process gas is supplied via a first hole formed to penetrate an upper cover of the substrate treating apparatus, and the other gas is supplied via a second hole formed to penetrate a sidewall of the substrate treating apparatus, or
the first process gas and the second process gas are supplied via one of the first hole and the second hole.

14. The substrate treating method of claim 1, wherein the substrate treating method includes an etch back process.

15. The substrate treating method of claim 1, wherein the substrate treating method is applied when manufacturing a lens module of a CMOS image sensor.

16. A substrate treating method, comprising:
inserting a substrate into a substrate treating apparatus;
injecting a first process gas into the substrate treating apparatus and treating the substrate to a first plasma using the first process gas; and
continuously injecting the first process gas into the substrate treating apparatus, additionally injecting a second process gas into the substrate treating apparatus, and treating the substrate to a second plasma using the first process gas and the second process gas,
wherein the second process gas includes a first component commonly included in the first process gas and a second component not included in the first process gas,
the first component is a fluorine component and the second component is a hydrogen component, and
the second process gas is injected in a larger amount than the first process gas.

17. A substrate treating apparatus, comprising:
a housing;
a substrate support unit installed in the housing and configured to support the substrate;
a plasma generation unit including a first electrode disposed in an upper part of the housing, a second electrode disposed to face the first electrode and included in the substrate support unit, a first high frequency power supply configured to supply RF power to the first electrode, and a second high frequency power supply configured to supply the RF power to the second electrode; and
a process gas supplying unit connected to the housing via a hole formed to penetrate an upper cover or a sidewall of the housing and configured to supply a process gas for treating the substrate into the housing,
wherein the process gas includes a first process gas and a second process gas in which at least some components are different from those of the first process gas.

18. The substrate treating apparatus of claim 17, wherein the process gas supplying unit first supplies the first process gas and then supply the first process gas and the second process gas together.

19. The substrate treating apparatus of claim 17, wherein the second process gas includes a first component commonly included in the first process gas and a second component not included in the first process gas.

20. The substrate treating apparatus of claim 17, wherein the process gas supplying unit supplies a larger amount of the second process gas than the first process gas.
